(19) United States
(12) Patent Application Publication
(10) Pub. No.: US 2010/0244274 A1
(43) Pub. Date: Sep. 30, 2010

(54) WIRING BOARD

(75) Inventors: Takeshi ISHITSUKA, Kawasaki (JP); Tomoyuki Akahoshi, Kawasaki (JP)

Correspondence Address: KRATZ, QUINTOS & HANSON, LLP, 1420 K Street, N.W., 4th Floor, WASHINGTON, DC, 20005, US

(73) Assignee: FUJITSU LIMITED, Kawasaki (JP)

(21) Appl. No.: 12/727,617

(22) Filed: Mar. 19, 2010

(30) Foreign Application Priority Data
Mar. 27, 2009 (JP) 2009-078148
Jan. 4, 2010 (JP) 2010-000166

(51) Int. Cl. H01L 23/522; H05K 1/11; H01L 23/48

(52) U.S. Cl. 257/774; 174/261; 257/E23.011; 257/E23.145

(57) ABSTRACT

A wiring board includes a first conductor constituting a signal line, a second conductor constituting a ground conductor or a power conductor, a dielectric layer disposed between and separately the first and second conductors, and a third conductor arranged between the first and second conductor, the third conductor being connected to the second conductor, and having a width narrower than that of the first conductor, the third conductor entirely opposing the first conductor, the entire portion of the third conductor being covered by the first conductor.

### CROSS-REFERENCE TO RELATED APPLICATIONS

This application is based upon and claims the benefit of priority of the prior Japanese Patent Application No. 2009-78148 filed on Mar. 27, 2009, and the Japanese Patent Application No. 2010-000166 filed on Jan. 4, 2010, the entire contents of which are incorporated herein by reference.

### FIELD

An aspect of the embodiments discussed herein is directed to a wiring board.

### BACKGROUND

As LSI's have been large-scaled and their manufacturing processes have been complicated in recent years, the SIP (System in Package) technique of packaging different semiconductor chips in one body is becoming popular. This technique allows semiconductor chips produced by some manufactures or semiconductor chips of different types, such as optical semiconductor and mechanical semiconductor, to be mounted together, and thus may achieve multifunction semiconductor devices.

A known SIP includes, for example, two different semiconductor chips stacked one on the other on a lead frame. More specifically, in such a SIP, one semiconductor chip is mounted on a lead frame, and the other semiconductor chip is mounted on the underlying semiconductor chip.

The upper semiconductor chip of the SIP is bonded to the lead frame with a wire. Thus, a high-density semiconductor integrated circuit chip may be achieved.

A pair of chips or a CSP (Chip Size Package) may be mounted in a flip chip manner. In this technique, semiconductor chips are provided with gold or copper bumps thereon, and the semiconductor chips are mounted on a substrate having a metal layer for bonding the chips by connecting the bumps to the metal layer.

Substrates used for CSP's or flip-chip mounting include organic substrates, ceramic substrates, silicon substrates and glass substrates. Organic substrates are inexpensive, but do not allow fine, precise wiring to be formed.

Ceramic substrates, silicon substrates, glass substrates and the like are intrinsically intended for multilayer wiring using photo processes, and allow fine and precise conductor lines to be formed thereon. However, the use of these substrates increases the manufacturing cost in comparison with the case of using an organic substrate, and is therefore limited to processes requiring fine, precise wiring.

The substrate for CSP's or flip-chip mounting includes a surface metal layer to which the bumps are to be bonded, and conductor lines. The conductor lines may have a strip wiring structure whose upper and lower surfaces are grounded or provided with a power source, or a microstrip wiring structure whose either upper surface or lower surface is grounded or provided with a power source.

Accordingly, Japanese Laid-open Patent Publication No. 2004-134715 discusses a technique that a plurality of semiconductor chips, each having an internal circuit as well as an external connection circuit drawn from the internal circuit, are mounted on the same supporting substrate of this semiconductor device.

### SUMMARY

According to an aspect of an embodiment, a wiring board includes a first conductor constituting a signal line, a first conductor constituting a signal line, a second conductor constituting a ground conductor or a power conductor, a dielectric layer disposed between and separately the first and second conductors, and a third conductor arranged between the first and second conductor, the third conductor being connected to the second conductor, and having a width narrower than that of the first conductor, the third conductor entirely opposing the first conductor, the entire portion of the third conductor being covered by the first conductor.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are representations of the structure of a microstrip wiring board according to an embodiment;

FIGS. 2A-2D are each a sectional view of the state in a step of a manufacturing process of a microstrip wiring board according to a first embodiment;

FIGS. 3E-3G are each a sectional view of the state in a step of the manufacturing process subsequent to the step illustrated in FIG. 2D;

FIG. 4 is a representation of the effect of the microstrip wiring board according to the first embodiment;

FIG. 5 is a representation of the effect of the microstrip wiring board according to a second embodiment;

FIGS. 6A and 6B are representations of the structure of a microstrip wiring board according to a third embodiment;

FIGS. 7A and 7B are representations of the structure of a microstrip wiring board according to a fourth embodiment;

FIGS. 8A and 8B are schematic representations of a microstrip wiring structure according to a related art;

FIGS. 9A and 9B are representations of the structure of a semiconductor device including a microstrip wiring board according to a fifth embodiment; and

FIGS. 10A and 10B are representations of the structure of the microstrip wiring board according to the fifth embodiment.

### DESCRIPTION OF EMBODIMENTS

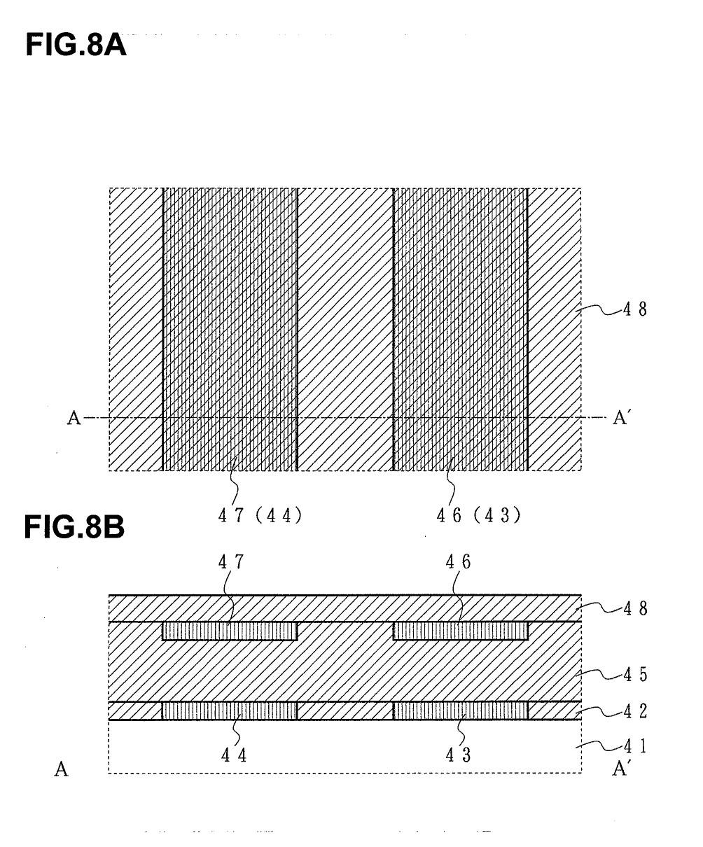

As described previously, FIGS. 8A and 8B illustrate a known microstrip wiring structure. As illustrated in FIG. 8B, a schematic sectional view of the microstrip wiring structure, ground lines 43 and 44 embedded in a SiO₂ layer 42 by a damascene method is formed on, for example, a glass substrate 41, and a SiO₂ insulating interlayer 45 is formed on the layer including the ground lines 43 and 44. Then, signal lines 46 and 47 are formed by the damascene method in wiring grooves formed in the insulating interlayer 45, and are covered with an insulating layer 48.

The microstrip wiring structure includes fewer layers and is more inexpensive than the strip wiring structure whose upper and lower surfaces are to be grounded or provided with a power source, and allows higher density wiring than coplanar wiring structures.

However, the number of terminals of a semiconductor chip tends to increase. Accordingly, it is required that the wiring density be increased. Unfortunately, if the intervals between the conductor lines (hereinafter may be referred to as line interval) are reduced to increase the wiring density, crosstalk noise is increased between the conductor lines.

The crosstalk noise between two conductor lines is caused by displacement of electrons in one signal line which is caused by an electric field generated in an insulating material between the conductor lines by a signal pulse transmitted through the other signal line. Accordingly, as the interval between the signal lines is reduced, the displacement of electrons in the signal line is increased to increase the crosstalk noise.

The present technique provides a wiring board and a semiconductor device that may achieve both the increase of wiring density and the reduction of crosstalk noise between conductor lines.

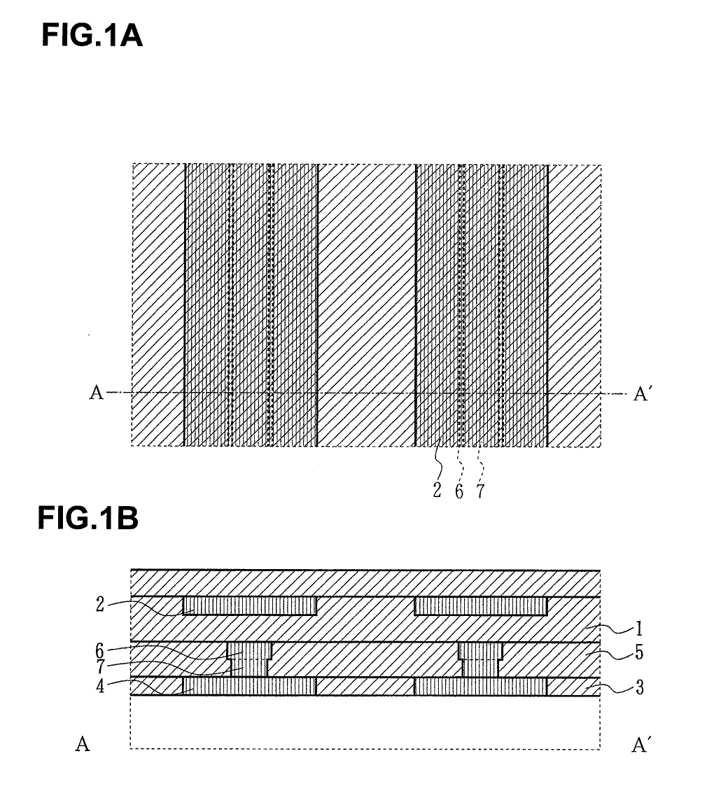

A microstrip wiring board according to an embodiment will now be described with reference to FIGS. 1A and 1B. FIGS. 1A and 1B illustrate the structure of a microstrip wiring board according to an embodiment. FIG. 1A is a schematic plan view of the microstrip wiring board, and FIG. 1B is a schematic sectional view taken along dotted chain line A-A′ in FIG. 1A.

As illustrated in FIGS. 1A and 1B, the microstrip structure of the wiring board includes a first layer 1 having first conductor films 2 intended for signal lines and a second layer 3 having second conductor films 4 intended for ground conductors or power conductors. In addition, in the present embodiment, third conductor films 6 are provided in a third layer 5 between the first conductor films 2 and the second conductor films 4.

Preferably, the third conductor film 6 has a smaller line width than the first conductor film 2 intended for the signal line, and the centerlines of the third conductor film 6 and the first conductor film 2 oppose each other so as to be substantially aligned with each other when viewed from above. The third conductor film 6 is thus completely covered with the first conductor film 2. More specifically, the third conductor film 6 is disposed within the portion of the third layer 5 corresponding to the line width of the first conductor film 2, that is, under the line width of the first conductor film 2. Preferably, the line width of the third conductor film 6 is 1/5 to 3/5 times the line width of the second conductor film 4.

Preferably, the third conductor film 6 is electrically connected to the second conductor film 4 with a fourth conductor 7 having a smaller width than the third conductor film 6. The fourth conductor 7 may be a via-conductor for interlayer connection or a portion of a wiring layer.

As described above, the crosstalk noise between conductor lines is caused by displacement of electrons in one signal line which is caused by an electric field generated in an insulating material between the conductor lines by a signal pulse transmitted through the other signal line. Accordingly, as the interval between the signal lines is reduced, the displacement of electrons in the signal line is increased to increase the crosstalk noise.

In the wiring structure of the present embodiment, the electric field generated in the insulating material between the signal line and the third conductor film 6 under the signal line is larger than the electric field generated in the insulating material between the signal lines. Accordingly, the electric field in the insulating material generated from one of two signal lines is deflected toward the third conductor film 6 owing to the presence of the third conductor film 6 under the signal line, and thus the electric field transmitted to the other signal line is reduced. Consequently, the crosstalk noise in a signal line caused by the other signal line may be reduced.

For such a wiring board, for example, a silicon, glass or ceramic substrate may be used. The insulating layer may be formed of an inorganic insulating material, such as silicon oxide, SiOC, or SiON, or an organic insulating material mainly containing an organic compound, such as polyimide. The conductor films are preferably formed of Cu or Al from the viewpoint of the electric conductivity and the cost.

By mounting semiconductor chips or CSP's on the wiring board and connecting the chips or CSP's to the microstrip structure, signals input to or output from the semiconductor chips or CSP's may be transmitted with low crosstalk.

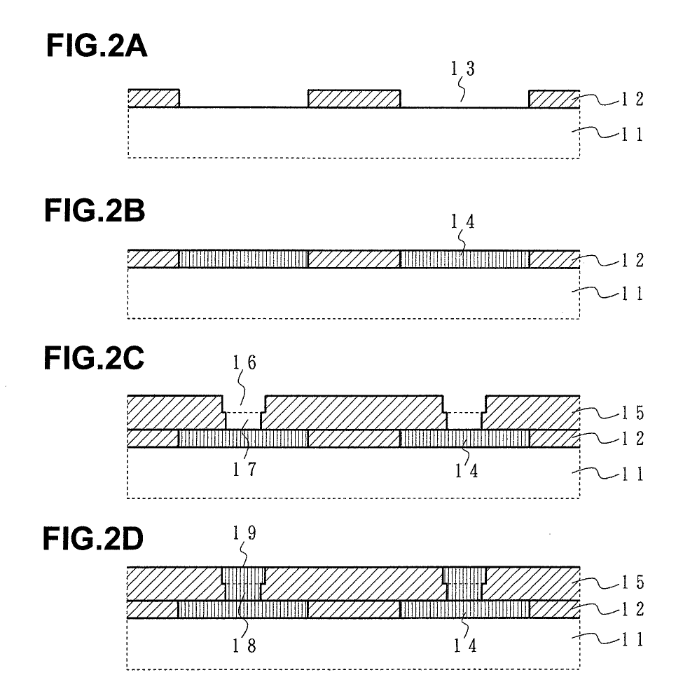

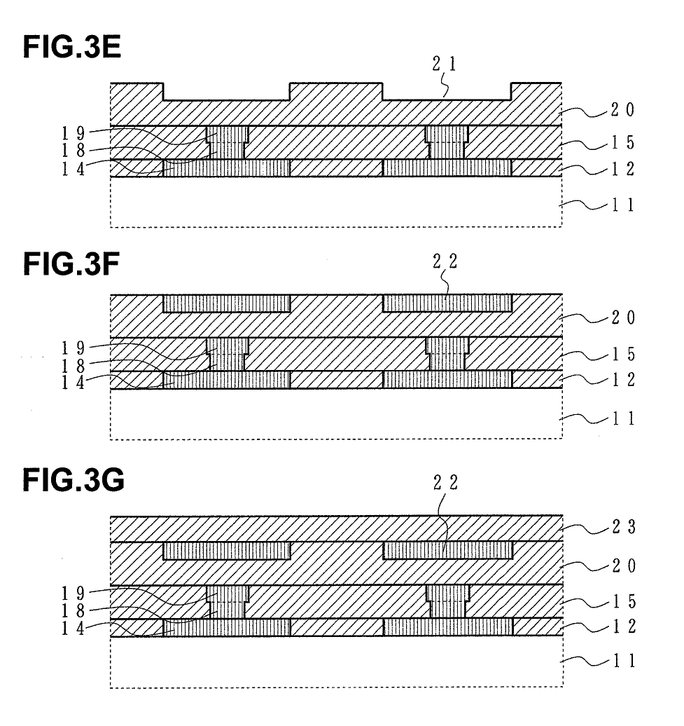

A microstrip wiring board according to a first embodiment will now be described with reference to FIGS. 2A to 4, predicated on the above structure. First, a process for manufacturing the microstrip wiring board of the first embodiment will be described with reference to FIGS. 2A to 3G. As illustrated in FIG. 2A, a SiO₂ layer 12 is formed to a thickness of about 0.4 μm on a silicon substrate 11 covered with a SiO₂ layer (not illustrated) having a thickness of, for example, about 0.7 μm, and subsequently, ground conductor-forming grooves 13 are formed in the SiO₂ layer 12.

Turning now to FIG. 2B, a Cu film is deposited over the entire surface of the substrate to fill the ground conductor-forming grooves 13. Undesired portions of the Cu film are removed by chemical mechanical polishing (CMP) to form ground conductors 14. The ground conductor 14 has a line width of about 10 μm and a wire length of about 5 mm, and is disposed at an interval of about 7 μm from the adjacent ground conductor 14.

Turning to FIG. 2C, a SiO₂ layer 15 is formed to a thickness of, for example, about 1 μm over the entire surface of the substrate, and then different wiring grooves 16 and 17 are formed in the SiO₂ layer 15. The wiring groove 16 has a width of about 3 μm and a depth of about 0.4 μm. The wiring groove 17 has a width of about 2.8 μm and reaches the ground conductor 14.

Turning to FIG. 2D, a Cu film is deposited over the entire surface of the substrate to fill the wiring grooves 16 and 17. Undesired portions of the Cu film are removed by CMP to form connection conductor films 18 connecting with the respective ground conductors and projecting conductors 19 at one time.

Turning now to FIG. 3E, a SiO₂ layer 20 is formed to a thickness of, for example, about 3 μl on the entire surface of the substrate, and signal line-forming grooves 21 having a width of about 10 μm and a depth of about 0.9 μm are formed in the SiO₂ layer 20. The signal line-forming groove 21 lies within the portion over the ground conductor 14 corresponding to the line width of the ground conductor 14. Hence, the signal line-forming groove has a width of about 10 μm and is disposed at an interval of about 7 μm from the adjacent groove.

Turning to FIG. 3F, a Cu film is deposited over the entire surface of the substrate to fill the signal line-forming grooves 21. Undesired portions of the Cu film are removed by CMP to form signal lines 22. Hence, the signal line 22 is formed at a distance of about 2 μm from the projecting conductor 19. Subsequently, a SiO₂ layer 23 is formed to a thickness of, for example, about 0.6 μm, as illustrated in FIG. 3G, and via-conductors (not illustrated) are formed in the SiO₂ layer 23. Thus, a microstrip wiring board of the first embodiment is completed.

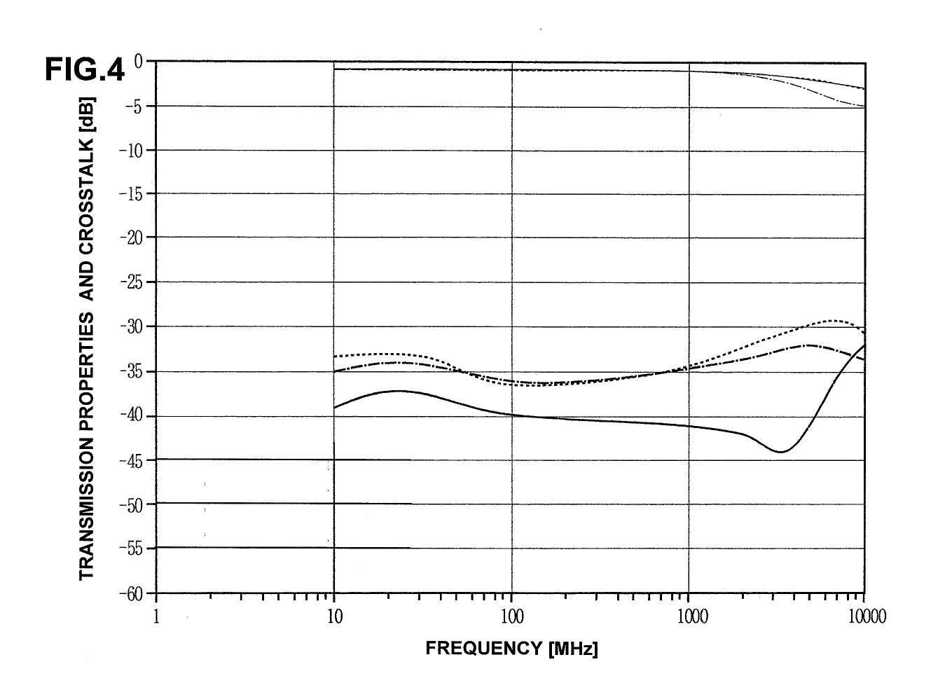

FIG. 4 illustrates the effect of the microstrip wiring board of the first embodiment, including the transmission properties of the wiring boards of the first embodiment and Comparative Examples 1 and 2. The wiring board of Comparative Example 1 does not have projecting conductors or connection conductors. The wiring board of Comparative Example 2 is provided with ground conductors at the positions of the projecting conductors of the first embodiment so that the signal line and the ground conductor have a distance of about 2 μm. In Comparative Examples 1 and 2, the ground conductor and the signal line each have a line width of about 10 μm, and are each disposed at an interval of about 7 μm from the adjacent conductor line. The signal transmittance and the crosstalk illustrated in FIG. 4 were obtained by analysis using simulation software HF SS (produced by Ansoft). The thin solid line in FIG. 4 indicates the transmission property of the first embodiment in the range from 10 MHz to 6000 MHz. The thin broken line in FIG. 4 indicates the transmission property of the Comparative Example 1 in the range from 10 MHz to 6000 MHz. The thin chain line in FIG. 4 indicates the transmission property of the Comparative Example 2 in the range from 10 MHz to 6000 MHz. The thick solid line in FIG. 4 indicates the crosstalk profile of the first embodiment in the range from 10 MHz to 6000 MHz. The thick broken line in FIG. 4 indicates the crosstalk profile of the Comparative Example 1 in the range from 10 MHz to 6000 MHz. The thick chain line in FIG. 4 indicates the crosstalk profile of the Comparative Example 2 in the range from 10 MHz to 6000 MHz.

As illustrated in FIG. 4, the signal transmittances of the first embodiment and Comparative Example 2 hardly have a difference. On the other hand, the crosstalk profiles are different, and the wiring board of the first embodiment illustrates a crosstalk 3 to 11 dB lower than in Comparative Examples 1 and 2.

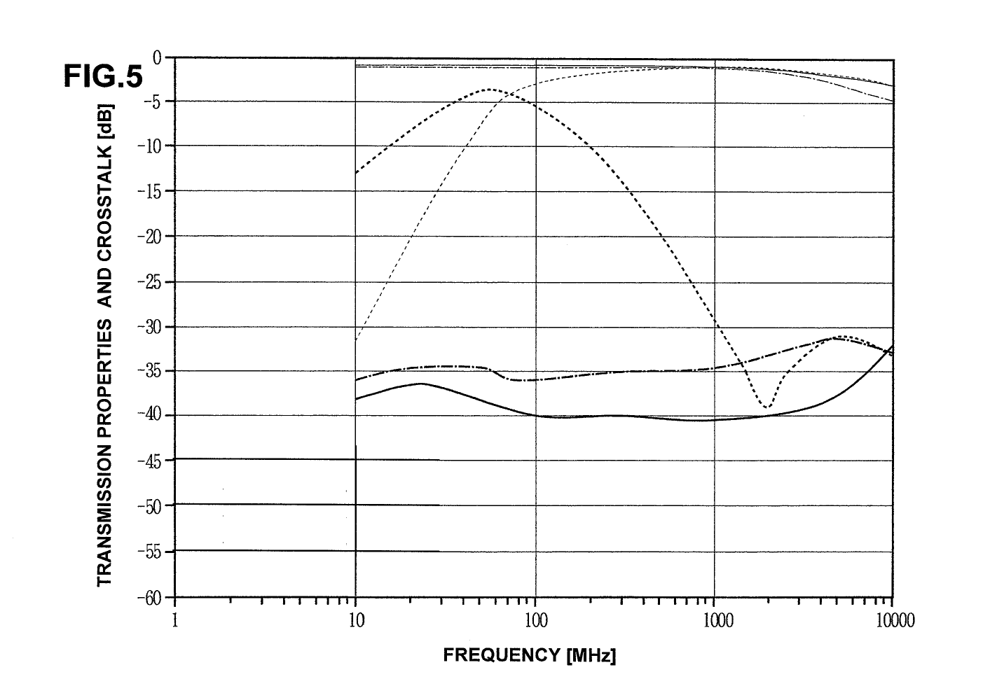

A microstrip wiring board according to a second embodiment will now be described with reference to FIG. 5. The wiring board of the second embodiment has the same structure and may be manufactured in the same process as in the first embodiment except that the ground conductors and the signal lines are disposed at intervals of about 6 μm. Only the effect of the second embodiment will be described below. FIG. 5 illustrates the transmission properties of the wring boards of the second embodiment, Comparative Example 1 not having the projecting conductors or connection conductors, and Comparative Example 2 in which ground conductors are provided at the positions of the projecting conductors. The signal transmittance and the crosstalk illustrated in FIG. 5 were obtained by analysis using simulation software HF SS (produced by Ansoft). The thin solid line in FIG. 5 indicates the transmission property of the second embodiment in the range from 10 MHz to 6000 MHz. The thin broken line in FIG. 5 indicates the transmission property of the Comparative Example 1 in the range from 10 MHz to 6000 MHz. The thin chain line in FIG. 5 indicates the transmission property of the Comparative Example 2 in the range from 10 MHz to 6000 MHz. The thick solid line in FIG. 5 indicates the crosstalk profile of the second embodiment in the range from 10 MHz to 6000 MHz. The thick broken line in FIG. 5 indicates the crosstalk profile of the Comparative Example 1 in the range from 10 MHz to 6000 MHz. The thick chain line in FIG. 5 indicates the crosstalk profile of the Comparative Example 2 in the range from 10 MHz to 6000 MHz.

As illustrated in FIG. 5, the signal transmittances of the second embodiment and Comparative Example 1 hardly have a difference. On the other hand, the crosstalk profiles are different, and the wiring board of the second embodiment illustrates a crosstalk 1.5 to 31 dB lower than in Comparative Example 1 and 2 to 8 dB lower than in Comparative Example 2.

The above results illustrate that if the line interval between the conductor liens is reduced, that is, if the wiring density is increased, the microstrip structure of embodiments may produce a greater effect in reducing crosstalk than the known microstrip structures. Accordingly, the effect of the technique becomes more remarkable as the integration degree is increased, and the structure according to an embodiment may more advantageously be applied.

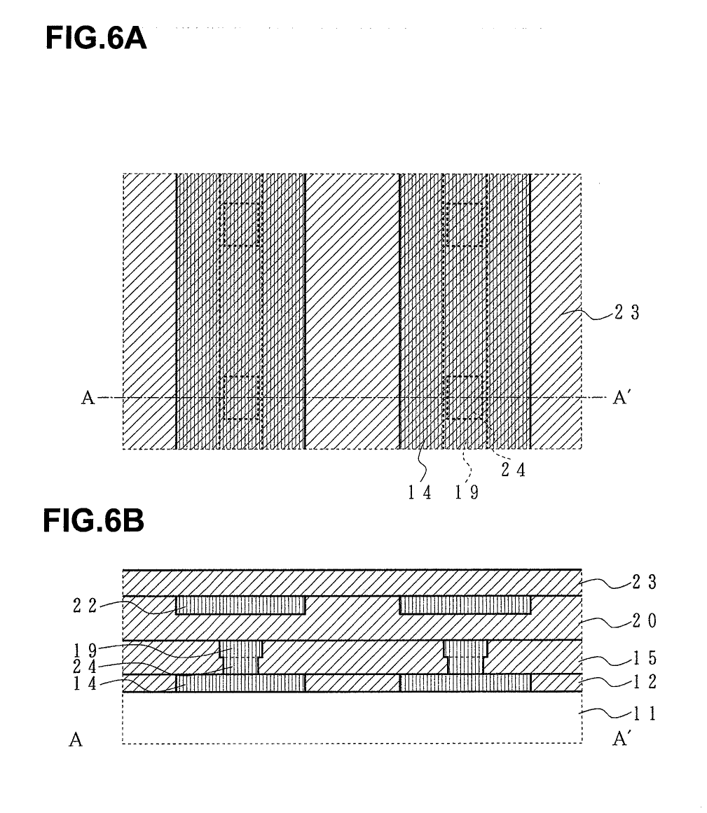

Referring now to FIGS. 6A and 6B, a microstrip wiring board according to a third embodiment will be described below. FIGS. 6A and 6B illustrate the structure of the microstrip wiring board according to the third embodiment. FIG. 6A is a schematic plan view of the microstrip wiring board, and FIG. 6B is a sectional view taken along line A-A′ in FIG. 6A.

As illustrated in FIG. 6B, a SiO₂ layer 12 is formed to a thickness of, for example, about 0.4 μm on a silicon substrate 11 covered with a SiO₂ film (not illustrated) having a thickness of, for example, about 0.7 μm, and then ground conductor-forming grooves are formed in the SiO₂ layer 12, as in the first embodiment.

Subsequently, a Cu film is deposited over the entire surface of the substrate to fill the ground conductor-forming grooves. Undesired portions of the Cu film are removed by CMP to form ground conductors 14. The ground conductor 14 has a line width of about 10 μm and a wire length of about 5 mm, and is disposed at an interval of about 7 μm from the adjacent ground conductor 14.

Subsequently, a SiO₂ layer 15 is formed to a thickness of, for example, about 1 μm over the entire surface of the substrate. Then, wiring grooves having a width of about 3 μm and a depth of about 0.4 μm are formed in the SiO₂ layer 15, and also via-holes of about 2.8 μm square reaching the ground conductor 14 are formed at a pitch of, for example, about 20 μm. Subsequently, a Cu film is deposited over the entire surface of the substrate to fill the wiring grooves and via-holes. Undesired portions of the Cu film are removed by CMP to form projecting conductors 19 and connection via-conductors 24 connecting with the ground conductor at one time.

Then, a SiO₂ layer 20 is formed to a thickness of, for example, about 3 μm over the entire surface of the substrate, and signal line-forming grooves having a width of about 10 μm and a depth of about 0.9 μm are formed in the SiO₂ layer 20. The signal line-forming groove lies within the portion over the ground conductor 14 corresponding to the line width of ground conductor 14. Hence, the signal line-forming groove has a width of about 10 μm and is disposed at an interval of about 7 μm from the adjacent groove.

Subsequently, a Cu film is deposited over the entire surface of the substrate to fill the signal line-forming grooves. Undesired portions of the Cu film are removed by CMP to form signal lines 22. Hence, the signal line 22 is formed at a distance of about 2 μm from the projecting conductor 19. Subsequently, a SiO₂ layer 23 is formed to a thickness of, for example, about 0.6 μm, and via-conductors (not illustrated) are formed in the SiO₂ layer 23. Thus, a microstrip wiring board of the third embodiment is completed.

In the third embodiment, the projecting conductor 19 is held at the same potential as the ground conductor 14 by the connection via-conductor 24, so that the microstrip wiring board of the present embodiment may exhibit the same transmission properties as that of the first embodiment.

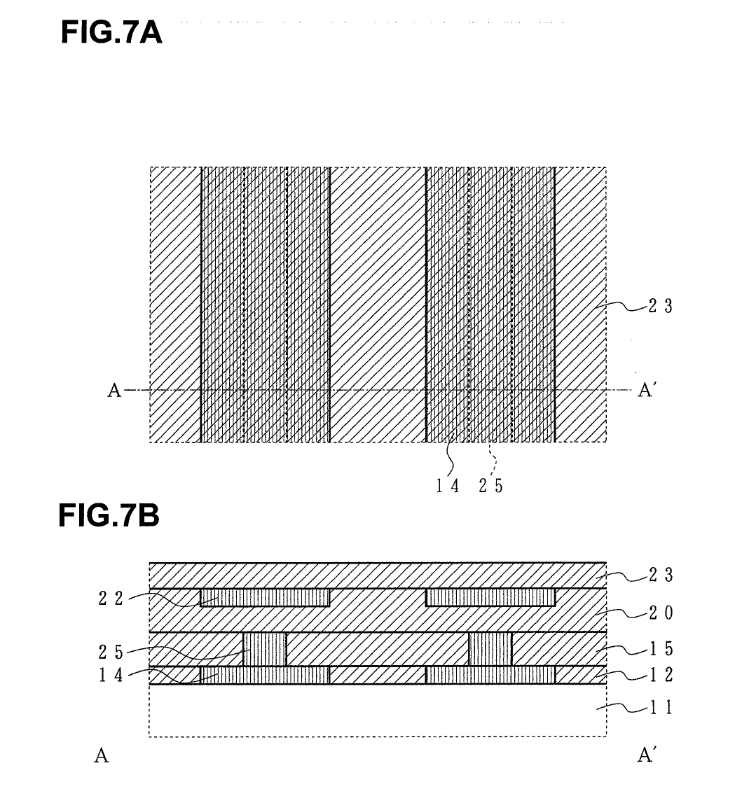

Turning now to FIGS. 7A and 7B, a microstrip wiring board according to a fourth embodiment will be described below. FIGS. 7A and 7B illustrate the structure of the microstrip wiring board according to the fourth embodiment. FIG. 7A is a schematic plan view of the microstrip wiring board, and FIG. 7B is a sectional view taken along line A-A′ in FIG. 7A.

As illustrated in FIG. 7B, a SiO₂ layer 12 is formed to a thickness of, for example, about 0.4 μm on a silicon substrate 11 covered with a SiO₂ film (not illustrated) having a thickness of, for example, about 0.7 μm, and then ground conductor-forming grooves are formed in the SiO₂ layer 12, as in the first embodiment.

Subsequently, a Cu film is deposited over the entire surface of the substrate to fill the ground conductor-forming grooves. Undesired portions of the Cu film are removed by CMP to form ground conductors 14. The ground conductor 14 has a line width of about 10 μm and a wire length of about 5 mm, and is disposed at an interval of about 7 μm from the adjacent ground conductor 14.

Subsequently, a SiO₂ layer 15 is formed to a thickness of, for example, about 1 μm over the entire surface of the substrate, and then wiring grooves having a width of about 3 μm are formed to reach the ground conductors 14. Subsequently, a Cu film is deposited over the entire surface of the substrate to fill the wiring grooves. Undesired portions of the Cu film are removed by CMP to form projecting conductors 25 connecting with the ground conductors 14.

Then, a SiO₂ layer 20 is formed to a thickness of, for example, about 3 μm over the entire surface of the substrate, and signal line-forming grooves having a width of about 10 μm and a depth of about 0.9 μm are formed in the SiO₂ layer 20. The signal line-forming groove lies within the portion over the ground conductor 14 corresponding to the line width of the ground conductor 14. Hence, the signal line-forming groove has a width of about 10 μm and is disposed at an interval of about 7 μm from the adjacent groove.

Subsequently, a Cu film is deposited over the entire surface of the substrate to fill the signal line-forming grooves. Undesired portions of the Cu film are removed by CMP to form signal lines 22. The signal line 22 is disposed at a distance of about 2 μm from the projecting conductor 25. Subsequently, a SiO₂ layer 23 is formed to a thickness of, for example, about 0.6 and via-conductors (not illustrated) are formed in the SiO₂ layer 23. Thus, a microstrip wiring board of the fourth embodiment is completed.

In the fourth embodiment, connection conductor films or connection via-conductors are not provided, but instead, thick projecting conductors 25 having the same potential as the ground conductor 14 are formed. Thus, the microstrip wiring board of the present embodiment may exhibit the same transmission properties as that of the first embodiment.

Although the present technique has been described with reference to embodiments, it is not limited to the disclosed embodiments, and various modifications may be made without departing from the scope and spirit of the invention. For example, while the microstrip wiring structure of the above-described embodiments has signal lines and ground conductors, the ground conductors may be replaced with power lines so that the microstrip wiring structure includes the power lines and signal lines.

Although the ground conductor and the signal line of the above embodiments each have a line width of about 10 μm and are each disposed at an interval of about 6 or 7 μm from the adjacent conductor line, the line width and the line interval are simply examples, and may be varied as desired.

Although the projecting conductors of the above embodiments have a width of about 3 μl, it is not limited to about 3 μm, but depends on the line width of the ground conductor. Preferably, the width of the projecting conductor is 1/5 to 3/5 times the line width of the ground conductor. A projecting conductor having a width of less than 1/5 times may not function as intended. A projecting conductor having a width of more than 3/5 times results in the same structure as in Comparative Example 2, and there is no point in providing the projecting conductor.

Although a SiO₂ coated silicon substrate is used as the substrate in the above embodiments, the substrate is not limited to a silicon substrate, and other insulating substrates may be used including, for example, glass substrates and ceramic substrates.

Although in the above embodiments, the conductors are covered with a SiO₂ layer, the insulating layer covering the conductors is not limited to the SiO₂ layer, and may be made of other inorganic insulating materials containing silicon oxide, such as SiOC and SiON. Alternatively, organic insulating materials mainly containing an organic compound, such as polyimide, may be used without limiting to inorganic insulating materials.

Although the conductor liens of the above embodiments are formed of Cu by a damascene method, the material of the conductors is not limited to Cu and may be a highly electroconductive materials, such as Al. For example, Al conductors may be formed by common etching, but not by damascene method. In this instance, however, the projecting conductors and the connection conductor films or connection via-conductors are formed in different steps.

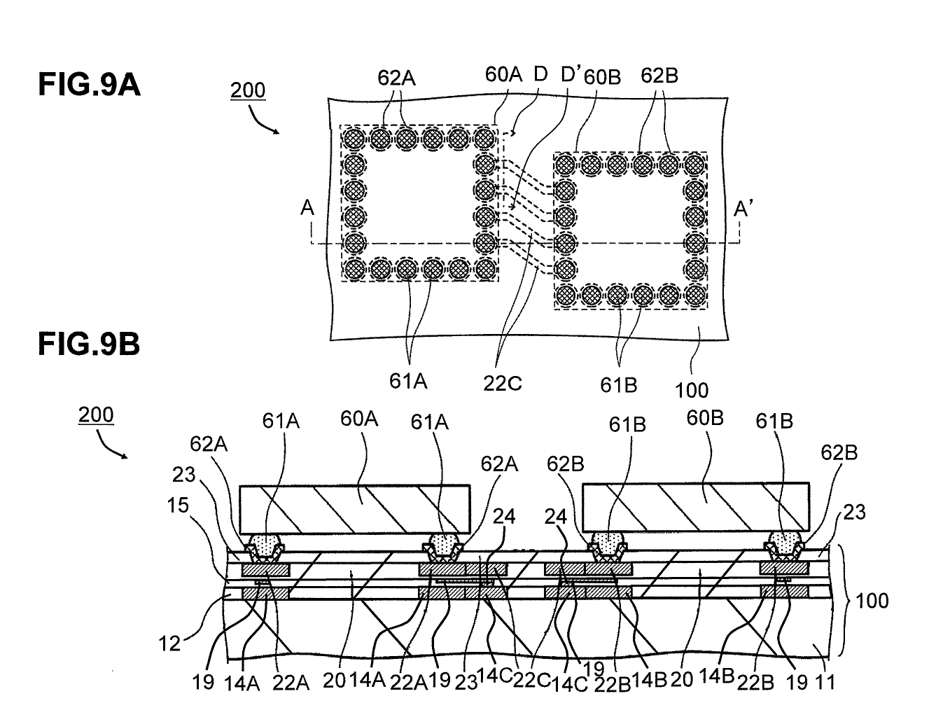

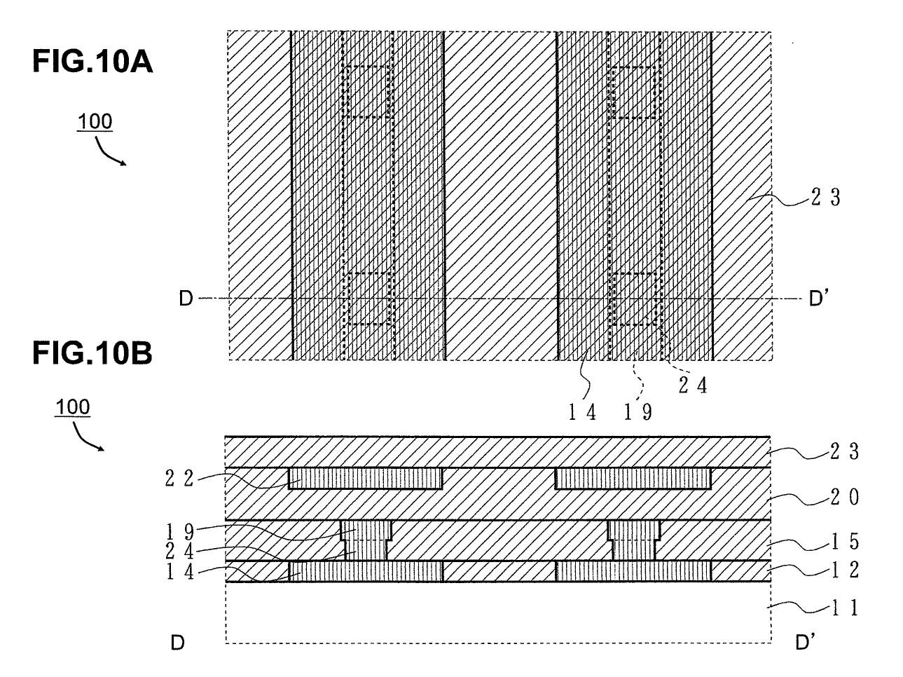

Turning now to FIGS. 9A and 9B and 10A and 10B, a semiconductor device 200 including a microstrip wiring board will be described according to a fifth embodiment.

FIGS. 9A and 9B illustrate the main part of the semiconductor device 200. FIG. 9A is a schematic plan view of the main part of the semiconductor device 200, and FIG. 9B is a schematic sectional view taken along line A-A′ in FIG. 9A. FIG. 9B also illustrates semiconductor elements 60A and 60B mounted on the wiring board 100. In FIG. 9A, the semiconductor elements 60A and 60B are represented by dashed lines for easy understanding of the plane structure of the wiring board 100. The fifth embodiment will be described using the same reference numerals for the same parts as in the first to fourth embodiments, and the same description will not be repeated.

The wiring board 100 includes a silicon substrate 11, a SiO₂ layer 12, ground conductors 14A, 14B and 14C, another SiO₂ layer 15, projecting conductors 19, another SiO₂ layer 20, signal lines 22A, 22B and 22C, still another SiO₂ layer 23, connection via-conductors 24, and connection terminals 62A and 62B.

The silicon substrate 11 is used as the base of the wiring board 100. A SiO₂ layer 12 is formed on the silicon substrate 11.

The ground conductors 14A, 14B and 14C are formed on the silicon substrate 11.

Another SiO₂ layer 15 is formed over the foregoing SiO₂ layer 12 and the ground conductors 14A, 14B and 14C.

Each projecting conductor 19 is disposed within the portion over the SiO₂ layer 12 corresponding to the line width of the ground conductor 14A, 14B or 14C.

The connection via-conductor 24 is formed in a via-hole passing through the SiO₂ layer 15 in the portion over the ground conductor 14C, and electrically connects the ground conductor 14C and the projecting conductor 19.

Another SiO₂ layer 20 is formed on the foregoing SiO₂ layer 15 and the projecting conductors 19.

The signal line 22A is disposed within the portion of the SiO₂ layer 20 corresponding to the line width of the ground conductor 14A over the ground conductor 14A with the projecting conductor 19 therebetween.

The signal line 22B is disposed within the portion of the SiO₂ layer 20 corresponding to the line width of the ground conductor 14B over the ground conductor 14B with the projecting conductor 19 therebetween.

The signal line 22C is disposed within the portion of the SiO₂ layer 20 corresponding to the line width of the ground conductor 14C over the ground conductor 14C with the projecting conductor 19 therebetween. The signal line 22C electrically connects the signal line 22A and the signal line 22B.

Another SiO₂ layer 23 is formed over the foregoing SiO₂ layer 20 and the signal lines 22A, 22B and 22C.

Connection terminals 62A are formed in openings in the SiO₂ layer 23 exposing part of the signal line 22A and electrically connect with the signal line 22A. More specifically, the upper surface of the signal line 22A and the lower surfaces of the connection terminals 62A directly come in contact with each other to establish an electrical connection between the signal line 22A and the connection terminals 62A, as illustrated in FIG. 9B. The upper surface of the signal line 22A and the lower surfaces of the connection terminals 62A may be connected to each other with conductor films (not illustrated). The connection terminals 62A are formed in a pattern in such a manner that each terminal continues from the opening in the SiO₂ layer 23 to the surface of the signal line 22A. The connection terminal 62A has, for example, a U-shaped section.

Alternatively, the connection terminals 62A may be spots selectively embedded in the SiO₂ layer 23, or may be pads (electrode pads). Furthermore, the connection terminals 62A may be pads selectively disposed only on the surface of the SiO₂ layer 23.

Connection terminals 62B are formed in openings in the SiO₂ layer 23 exposing part of the signal line 22B and electrically connect with the signal line 22B. More specifically, the upper surface of the signal line 22B and the lower surfaces of the connection terminals 62B directly come in contact with each other to establish an electrical connection between the signal line 22B and the connection terminals 62B, as illustrated in FIG. 9B. The upper surface of the signal line 22B and the lower surfaces of the connection terminals 62B may be connected to each other with conductor layers (not illustrated). The connection terminals 62B are formed in a pattern in such a manner that each terminal continues from the opening in the SiO₂ layer 23 to the surface of the signal line 22B. The connection terminal 62B has, for example, a U-shaped section.

Alternatively, the connection terminals 62B may be spots selectively embedded in the SiO₂ layer 23, or may be pads (electrode pads), as with the connection terminals 62A.

The semiconductor element 60A is electrically connected to the connection terminals 62A with bump electrodes 61A formed on the semiconductor element 60A. The semiconductor element 60A is mounted on the wiring board 100 with the bump electrodes 61A in a flip chip manner. The bump electrodes 61A may be made of, for example, tin (Sn)-lead (Pb) eutectic solder, lead (Pb)-free binary tin (Sn)-silver (Ag) solder, or lead (Pb)-free ternary tin(Sn)-silver (Ag)-copper (Cu) solder.

The semiconductor element 60B is electrically connected to the connection terminals 62B with bump electrodes 61B formed on the semiconductor element 60B. The semiconductor element 60B is mounted on the wiring board 100 with the bump electrodes 61B in a flip chip manner. As with the bump electrodes 61A, the bump electrodes 61B may be made of, for example, tin (Sn)-lead (Pb) eutectic solder, lead (Pb)-free binary tin (Sn)-silver (Ag) solder, or lead (Pb)-free ternary tin(Sn)-silver (Ag)-copper (Cu) solder.

Turning now to FIGS. 10A and 10B, the microstrip wiring board according to the fifth embodiment will be described. FIGS. 10A and 10B illustrate the structure of the microstrip wiring board according to the fifth embodiment. FIG. 10A is a schematic fragmentary plan view of the microstrip wiring board, and FIG. 10B is a sectional view taken along line D-D′ in FIGS. 9A and 10A. The following description uses the same reference numerals for the same parts as in the first to fourth embodiments, and the same description will be omitted.

As illustrated in FIG. 10B, a SiO₂ layer 12 is formed to a thickness of, for example, about 0.4 μm on a silicon substrate 11 covered with a SiO₂ film (not illustrated) having a thickness of, for example, about 0.7 μm, and then ground conductor-forming grooves are formed in the SiO₂ layer 12, as in the first embodiment.

Subsequently, a Cu film is deposited over the entire surface of the substrate to fill the ground conductor-forming grooves. Undesired portions of the Cu film are removed by CMP to form the ground conductors 14. The ground conductor 14 has a line width of about 10 μm and a wire length of about 5 mm, and is disposed at an interval of about 7 μm from the adjacent ground conductor 14.

Subsequently, another SiO₂ layer 15 is formed to a thickness of, for example, about 1 μm over the entire surface of the foregoing SiO₂ layer 12 having the ground conductor 14 therein. Then, wiring grooves having a width of about 3 μm and a depth of about 0.4 μm are formed in the SiO₂ layer 15, and also via-holes of about 2.8 μm square reaching the ground conductors 14 are formed at a pitch of, for example, about 20 μm. Subsequently, a Cu film is deposited over the entire surface of the substrate to fill the wiring grooves and via-holes. Undesired portions of the Cu film are removed by CMP to form the projecting conductors 19 and the connection via-conductors 24 connecting with the ground conductor at one time.

Then, another SiO₂ layer 20 is formed to a thickness of, for example, about 3 μm over the entire surface of the substrate, and signal line-forming grooves having a width of about 10 μm and a depth of about 0.9 μm are formed in the SiO₂ layer 20. The signal line-forming groove lies within the portion over the ground conductor 14 corresponding to the line width of the ground conductor 14. Hence, the signal line-forming groove has a width of about 10 μm and is disposed at an interval of about 9 μm from the adjacent groove.

Subsequently, a Cu film is deposited over the entire surface of the substrate to fill the signal line-forming grooves. Undesired portions of the Cu film are removed by CMP to form the signal lines 22. Hence, the signal line 22 is formed at a distance of about 2 μm from the projecting conductor 19. Subsequently, another SiO₂ layer 23 is formed to a thickness of, for example, about 0.6 μm, and via-conductors (not illustrated) are formed in the SiO₂ layer 23. Thus, a microstrip wiring board of the fifth embodiment is completed.

In the semiconductor device 200 of the present embodiment, the projecting conductor 19 causes an electric field distribution from the signal line to the ground conductor, and, thus, the same effect of the first embodiment may be produced. By mounting semiconductor elements or CSP's on the wiring board 100 and connecting the elements or CSP's to the microstrip structure, crosstalk noise in a signal line caused by the other signal line may be reduced. Consequently, signals input to or output from the semiconductor element or CSP may be reliably transmitted.

All examples and conditional language recited herein are intended for pedagogical purposes to aid the reader in understanding the embodiment and the concepts contributed by the inventor to furthering the art, and are to be construed as being without limitation to such specifically recited examples and conditions, nor does the organization of such examples in the specification relate to a illustrating of the superiority and inferiority of the embodiment. Although the embodiments of the present invention have been described in detail, it should be understood that the various changes, substitutions, and alterations could be made hereto without departing from the spirit and scope of the invention.

What is claimed is:

1. A wiring board comprising:
a first conductor constituting a signal line;
a second conductor constituting a ground conductor or a power conductor;
a dielectric layer disposed between and separately the first and second conductors; and
a third conductor arranged between the first and second conductor, the third conductor being connected to the second conductor, and having a width narrower than that of the first conductor, the third conductor entirely opposing the first conductor, the entire portion of the third conductor being covered by the first conductor.

2. The wiring board according to claim 1, wherein the third conductor is connected to the second conductor and a plurality of via-conductors for interlayer connection.

3. The wiring board according to claim 1, further comprising a fourth conductor formed between the third and second conductor, the third conductor having a width narrower than that of the third conductor, the fourth conductor connected to a surface of the third and second conductors.

4. The wiring board according to claim 3, wherein the third and fourth conductor extends in a direction parallel with each other, the third and fourth conductors being aligned to a center line of the line width of the first conductor, and the center lines of the third and fourth conductors along the direction are aligned with each other.

5. The wiring board according to claim 3, wherein the dielectric layer is made of a silicon oxide or an organic compound.

6. A semiconductor device comprising:
a semiconductor chip having a connecting terminal;
a wiring board having a connector being connected to the connecting terminal of the semiconductor chip, the wiring board including:
a first conductor constituting a signal line;
a second conductor constituting a ground conductor or a power conductor;
a dielectric layer disposed between and separately the first and second conductors; and
a third conductor arranged between the first and second conductor, the third conductor being connected to the second conductor, and having a width narrower than that of the first conductor, the third conductor entirely opposing the first conductor, the entire portion of the third conductor being covered by the first conductor.

7. The semiconductor device according to claim 6, wherein the third conductor is connected to the second conductor and a plurality of via-conductors for interlayer connection.

8. The semiconductor device according to claim 6, further comprising a fourth conductor formed between the third and second conductor, the third conductor having a width narrower than that of the third conductor, the fourth conductor connected to a surface of the third and the second conductors.

9. The semiconductor device according to claim 8, wherein the third and fourth conductor extends in a direction parallel with each other, the third and fourth conductors being aligned to a center line of the line width of the first conductor, and the center lines of the third and fourth conductors along the direction are aligned with each other.

10. The semiconductor device according to claim 8, wherein the dielectric layer is made of a silicon oxide or an organic compound.

11. A semiconductor device comprising:
a plurality of semiconductor chips having a connecting terminal;
a wiring board having a connector being connected to the connecting terminal of the semiconductor chip, the wiring board including:
a first conductor constituting a signal line;
a second conductor constituting a ground conductor or a power conductor;
a dielectric layer disposed between and separately the first and second conductors; and
a third conductor arranged between the first and second conductor, the third conductor being connected to the second conductor, and having a width narrower than that of the first conductor, the third conductor entirely opposing the first conductor, the entire portion of the third conductor being covered by the first conductor;
wherein the plurality of semiconductor devices are connected to the first conductive layer, and the plurality of semiconductor devices are respectively connected via the first conductive layer.

12. The semiconductor device according to claim 11, wherein the third conductor is connected to the second conductor and a plurality of via-conductors for interlayer connection.

13. The semiconductor device according to claim 11, further comprising a fourth conductor formed between the third and second conductor, the third conductor having a width narrower than that of the third conductor, the fourth conductor connected to a surface of the third and the second conductors.

14. The semiconductor device according to claim 13, wherein the third and fourth conductor extends in a direction parallel with each other, the third and fourth conductors being aligned to a center line of the line width of the first conductor, and the center lines of the third and fourth conductors along the direction are aligned with each other.

15. The semiconductor device according to claim 13, wherein the dielectric layer is made of a silicon oxide or an organic compound.
